(19) United States
(12) Patent Application Publication
(10) Pub. No.: US 2009/0317708 A1
(43) Pub. Date: Dec. 24, 2009

(54) PLASTIC LAMINATE FILM

(76) Inventors: Oliver Brandl, Konstanz (DE); Erwin Pasbrig, Singen (DE); Hans-Rudolf Nägeli, Neuhausen (CH); Wolfgang Lohwasser, Gailingen (DE); Thomas Hentschel, Bonn (DE)

Correspondence Address: BANNER & WITCOFF, LTD., TEN SOUTH WACKER DRIVE, SUITE 3000, CHICAGO, IL, 60606, US

(21) Appl. No.: 12/374,960

(22) PCT Filed: Jul. 11, 2007
(86) PCT No.: PCT/EP2007/006131

§ 371 Date: Jan. 23, 2009

(30) Foreign Application Priority Data
Jul. 24, 2006 (EP) 06405319.2

(51) Int. Cl. H01M 2/02; B32B 15/08; B32B 5/00; C23C 16/44; C23C 14/34; C23C 16/513

(52) U.S. Cl. 429/163; 428/622; 428/336; 428/220; 427/250; 204/192.1; 427/576

(57) ABSTRACT

Plastics composite foil for the sheathing of lithium-ion-polymer batteries and lithium-polymer batteries, comprising, arranged in mutual superposition, the following layers: a) a base foil composed of plastic b) a metal foil and c) a functional plastics layer, where at least one metal protective layer applied via a physical deposition process, such as vapour deposition processes or sputtering, an example being a chromium layer, has been arranged with thickness of from 0.1 to 1000 nm (nanometres) on the layer b), the metal foil, at least in the direction of the layer c), and/or on the layer c), the functional plastics layer, in the direction of the layer b), the metal foil, and/or in the functional plastics layer.

The present invention relates to a plastic laminate film containing the following layers, arranged in layers one upon the other, viz.,

a) a base film of plastic

b) a metal foil and

c) a functional plastic layer.

The invention also relates to the manufacture of the plastic laminate film and the use thereof as cladding for battery modules.

As a rule, battery modules i.e. the part of batteries which generates electric energy and accumulators (primary and secondary elements) feature a housing or cladding. For example battery modules of lithium-ion-polymer batteries or lithium-polymer batteries are essentially made up of a positive and a negative connection and, between these, a layer of electrolytic gel. For designated purposes the battery modules are enclosed in a form of cladding. The cladding may be in the form of a bag or pre-formed packaging of a multi-layer laminate made up of plastics. As the gel-type electrolyte contains aggressive salts and solvents, and can form reactive gases with the residual moisture, there is a danger that the aggressive substances damage or destroy the cladding and as a result the equipment into which the battery has been incorporated. In order to increase the lifetime of the battery, the laminate may contain a barrier layer e.g. of aluminium foil. The aggressive substances cause the aluminium foil to be weakened or destroyed by corrosion or pitting, or the individual layers that make up the laminate or cladding may delaminate i.e. loosen their contact with each other. Likewise, the described chemical attack on the cladding applies also to other primary and secondary elements affected by chemical reactions.

Known from U.S. Pat. No. 6,761,994 is the cladding of battery modules of lithium-ion-polymer batteries or lithium-polymer batteries with plastic laminate films made up of a base layer of plastic, adhesive, an aluminium foil and a sealing layer. In order to improve the resistance of the aluminium foil to corrosion, a conversion layer is formed chemically on the surface of the aluminium foil by means of a phosphate-chromate treatment.

Known from EP 1 160 892 is a battery module packaging which contains a base layer, an aluminium layer, a chemical conversion layer formed by means of a phenolic resin, trivalent chromium phosphate and phosphoric acid, and an innermost layer of polypropylene resin.

The Japanese patent application 2002-075298 mentions a packaging material for polymeric batteries containing, amongst other components, an aluminium foil which is provided with a chrome-layer by wet chemical means using chromium-salts, inorganic acids such as phosphoric acid or hydrofluoric acid, and organic components.

To create the conversion layer by wet chemical means involves corrosive and highly toxic substances which in some cases are also dissolved in solvent solutions.

Creating chromium-layers which are deposited via wet chemical methods, in particular in the case of the thin aluminium foils employed here, is not only extremely complicated, but also results in toxic mixtures that are costly to dispose of.

The object of the present invention is to avoid the above mentioned disadvantages and to propose a plastic laminate film which is particularly suitable for cladding battery modules, a process for its manufacture and the use of the plastic laminate film.

That objective is achieved by way of the invention in that, by means of a physical deposition process, at least one protective metallic layer having a thickness of 0.1 to 1000 nm (nanometre) is provided on layer b), the metal foil, at least on the side facing layer c), and/or on layer c), the functional plastic layer facing layer b), the metal foil, and/or in the functional plastic layer.

Metal foils which may be used are ferrous or non-ferrous metal foils such as iron, steel, nickel, copper etc. The metal foils have a thickness of 12 to 200 μm, usefully 20 to 200 μm, preferably 25 to 75 μm and in particular 40 to 50 μm. Preferred are foils of aluminium and its alloys, whereby soft aluminium is preferred. Examples of foils of aluminium or aluminium alloys are those made of Al 99.0 or Al 99.5 or alloys of the types AA 1xxx and AA 8xxx, whereby the alloys AA 8006, AA 8014 and AA 8021 are particularly suitable. The foils of aluminium or aluminium alloys may have the above mentioned thickness. Typical thickness values for aluminium foils are 40, 45, 50, 60 and 100 μm.

The base film of plastic may contain one or more layers. For example, it may be a polyester film e.g. a polyethylene-terephthalate film (PET), a polyamide film, e.g. an oriented polyamide film (oPA), a polyolefin film e.g. an oriented polypropylene film (oP) or a film or layer containing an acidic denaturised polyolefin. If the base film contains a plurality of layers, then this may be two or more mutually adhesively bonded, extrusion laminated and/or hot calendared layers or films. Adhesively bonded layers or films may be processed using aqueous, solvent-containing or solvent-free adhesives. The thickness of the base film may be from 12 to 50 μm, usefully 15 to 25 μm. Typical thickness values for such films are 12, 15, 20, 23 and 25 μm. When employing the plastic laminate films according to the invention as cladding for battery modules, the base film is the outer side of the cladding i.e. it faces outwards.

The base film lies against the metal foil. In order to achieve the required bonding of the base film to the metal foil, an adhesive layer may be provided between the base film and the metal foil. The adhesives may be solvent-free, solvent-based or aqueous-based adhesives. In another version, in order to achieve adequate adhesion between the layers or films to be joined, the base film may contain acid-denaturised polyolefines, or a layer of acid-denaturised polyolefin may be provided between the base film and the metal foil. The base film may also be joined to the metal foil by means of curtain coating, extrusion lamination and/or by hot calendaring. If desired a primer may be employed in the above mentioned processes. In order to improve the bonding, a plasma or corona pre-treatment or a chemical pre-treatment may be applied to one or both of the surfaces that are to be joined to each other.

The functional plastic layer may be made up of a single layer or several layers. If the functional plastic layer comprises a plurality of layers, then this may be two or more mutually bonded layers or films joined together by adhesive lamination, extrusion lamination, hot-calendaring and/or curtain coating. Preferred are two or more coextruded layers. The functional layer contains e.g. polyamides such as oriented polyamide (oPA), polyolefins such as polypropylene, oriented polypropylene (oPP) or polyethylene, polyesters such as polyethylene-terephthalate (PET), acid-denaturised polyolefins such as acid-denaturised polypropylene-ethylene, metallocene-containing polyolefins such as metallocene-containing polypropylene or ethylene, methyl-acrylic-acid-containing olefins such as methyl-acrylic-acid-containing polypropylene or ethylene. In the case of the polypropylenes this may also be a blend of propylene and polyethylene or other polyolefins. One may also employ copolymers of propylene and ethylene or other olefins or cyclo-olefinic copolymers (CoC), cyclo-olefinic polymers (COP) or polymers and copolymers of acrylnitrile such as acrylnitrile/methacrylate-copolymers (BAREX®). Preferred is a functional layer that contains at least two layers viz., a polypropylene layer and/or a metallocene-containing propylene layer and a polypropylene layer containing methacrylic-acid. The overall thickness of the functional layer may e.g. be from 12 to 100 μm whereby the individual layers are 15 to 60 μm thick and two or more layers together may be from 40 to 100 μm thick.

When employing the plastic laminate films according to the invention as cladding for battery modules, the functional plastic layer forms the inner side of the cladding i.e. it faces inwards towards the battery module.

Typical examples of functional layer are a 30-50 μm thick layer of coextruded polypropylene or a 30 μm thick layer of coextruded polyethylene.

If the functional plastic laminate film is e.g. made up of two layers, then one layer faces the metal foil while the other layer faces the inner side or the battery module.

Typical examples of such layers are—facing the metal foil—of a layer of 15 μm thick oriented polyamide and—facing the inner side 30-50 μm thick coextruded polypropylene or—facing the metal foil—of a layer of 12 μm thick polyethylene-terephthalate and—facing the inner side—50 μm thick coextruded polypropylene or—facing the metal foil—of a layer of 15 μm thick oriented polyamide and—facing the inner side—30 μm thick coextruded polyethylene or—facing the metal foil—of a layer of 20 μm thick oriented polypropylene and—facing the inner side—30 to 50 μm thick coextruded polypropylene.

Likewise functional layers with three or more individual layers may also be employed.

Advantageously, the functional layer exhibits sealing properties i.e. the functional layer can be sealed e.g. by hot or cold sealing. The functional layer is usefully sealable onto other parts of the packaging and onto itself. If the functional layer is made up of a combination of several individual layers, then in particular the outermost free layer exhibits sealing properties or can be sealed or the outermost free layer is advantageously weldeable or can be bonded by means of an adhesive.

The base film lies against one side of the metal foil. The other side of the metal foil lies against the functional layer. An adhesive layer may be provided between the functional layer and the metal foil in order to achieve the necessary bonding between these layers. The adhesive may be solvent-free, solvent-based or water-based. In another version, in order to achieve the adequate bonding between the layers to be joined together, the functional layer may contain acid-denaturised polyolefins or, a layer of an acid-denaturised polyolefin may be provided between the functional layer and the metal foil. The functional layer may also be joined to the metal foil by extrusion lamination, extrusion coating and/or by hot-calendaring. If desired a primer may be employed in the mentioned processes. A plasma or corona treatment may be carried out on one or both of the surfaces to be joined together in order to improve the bonding,

The plastic laminate film according to the invention contains a protective metallic layer. The purpose of the protective metallic layer is to protect the metal foil from aggressive substances. In one version according to the present invention on the metal foil, made e.g. of aluminium or an aluminium alloy, there is a 0.1 to 1000 nm (nanometre) thick protective metallic layer. In an alternative version the metallic protective layer does not lie against the metal foil but instead against the functional layer. On joining together the metal foil and the functional layer, the protective metallic layer—if desired via an adhesive or bonding agent—comes to rest against one of the metal foil surfaces. The protective metallic layer may also be deposited on a layer or film of one of the above mentioned plastics which is processed with other layers or films of the above mentioned plastics to make a multiple-layer or multiple film functional layer. The protective metallic layer is then situated between two plastic layers of the functional layer.

Several protective metallic layers may be provided. A first protective metallic layer may be situated on the metallic foil and a second protective metallic layer may be provided on the functional layer, whereby in the plastic laminate film according to the invention the protective metallic layers lie against each other, if desired via an adhesive or bonding agent.

In a further version a protective metallic layer is provided on the metal foil and a protective metallic layer is provided between layers of plastic within the functional layer.

In yet another version a first protective metallic layer is provided on an outer side of the functional layer and a second protective metallic layer between two layers of plastic within the functional layer. The functional layer is joined to the metal foil via the outer lying first protective layer—in some cases via an adhesive or bonding agent.

In a further version a first protective metallic layer may be provided on the metal foil and a second protective metallic layer on the functional layer, whereby in the plastic laminate film the protective metallic layers lie against each other—in some cases via an adhesive or bonding agent—and a third protective metallic layer between two layers or coatings of plastic in the functional layer.

Each of the above mentioned protective metallic layers is deposited by means of a physical deposition process. Examples of physical deposition processes are vacuum vapour deposition and sputtering.

For the purposes of coating with a protective metallic layer, the metal foil or a plastic film or a metal-plastic film laminate is uncoiled in vacuum in a vacuum chamber, as individual sheets and in particular usefully from a coil or roll and exposed to an atmosphere of essentially vaporised or sputtered metal. The metal-containing vapour is deposited as a 0.1 to 1000 nm thick layer on at least one side of the metal foil. The metal foil with the vapour-deposited protective metallic layer may be coiled again continuously onto a counter coil or roll. The protective metallic layer may be e.g. of Cu, Au, Ag, Ni, Pd, Pt, Ti, Zr, Hf, V, Cr, Mo, W, Zn, Cd, Hg, Si, Ge, Sn, Pb, Fe, Ru, Os, Mn, Tc, Re, Ga, In, Tl, Bi or a mixture thereof. Preferred are Cr, Ti and Zr alone or as a mixture of a pair or all three metals; preferred in particular is Cr. Depending on the protective metallic layer required, the starting materials are selected of substances that contain or are comprised of the above mentioned elements. For example, the metal is placed in a vacuum chamber and via an electron beam gun which is directed at the target material, vaporised or sputtered using a sputtering method. The target material is e.g. a plate of the metal to be vaporised. If a mixture of metals is to be deposited, then a mixture of the said different metals or several metal plates of may be vaporised or sputtered. The vaporised or sputtered metal is deposited with a given thickness on the surface of the metal foil. The thickness of the metal deposited can be controlled e.g. via the rate of throughput of the metal foil and by the intensity of the electron beam or power of the sputtering cathode.

It has been found to be particularly useful to provide the metal foil or the plastic films or layers in the vacuum unit with a plasma pre-treatment e.g. with argon (Ar), nitrogen (N₂), NH₃, NOₓ (nitrous oxides) and preferably via oxygen plasma. The pre-treatment may take place directly in the vacuum unit or prior to coating. The plasma pre-treatment is to obtain particularly good bonding of the layers of metal foil, protective metal layer and the plastic films or layers to each other. The protective metal layer is preferably created by means of electron beam vaporisation with chromium as target material. Especially preferred is a plasma pretreatment using oxygen plasma and vapour deposition by electron beam vaporisation using chromium as target material.

An example of a process for depositing the protective metal layer during the production of a plastic laminate film according to the invention is such that the deposition of the protective metallic layer is performed using a chromium deposition process. The base film, joined to the aluminium foul, or the functional layer, may be exposed in a vacuum chamber to a plasma treatment in an oxygen plasma and then a chromium-containing cloud of vapour created by electron beam vaporisation, whereby the chromium is deposited on the free surface of the foil or layer. The chromium deposition process may be carried out in such a manner that a plastic-aluminium film e.g. of oriented polyethylene or polyester and an aluminium foil is exposed to a plasma treatment in an oxygen plasma and then a chromium-containing vapour cloud. The vapour cloud is formed from a chromium granulate which is heated and vaporised by an electron beam at 30 to 40 kV and beam current e.g. of 1.1 to 1.5 A. At a throughput rate of aluminium foil or functional layer of e.g. 120 m/min it is possible to create a chromium layer with a thickness of around 80 nm

In cases where the metal foil is passed over a coating roll in the vacuum chamber, the metal vapour is deposited only on the free side of the metal foil i.e. not on the side of the foil in contact with the coating roll. If the metal foil is passed through the vacuum chamber in a so called free-span manner, then both sides of the metal foil are coated. In order to maintain a high coating rate and to reduce the amount of energy and amount of target material used, usefully only one side of the metal foil is coated.

It is also possible to expose the metal foil which is already coated with the base film to the metal vapour in the vacuum chamber, and therefore coat the metal foil on the free side with the protective metal layer.

Thus, the present invention also relates to a process for manufacturing a plastic laminate film for use as battery cladding. In accordance with the process according to the invention a protective metallic layer can be deposited on at least one of the two surfaces of the metal foil. The protective metallic layer may also be provided on the surface of the functional layer which on the plastic laminate film faces the metal foil. Also the protective metallic layer may be provided between two layers or films of the functional layer. Also a first protective metallic layer may be provided on the functional layer—on the surface facing the metal foil—and a second protective metallic layer between two layers or films of the functional layer. The deposition of the protective metallic layer takes place by means of a physical deposition process whereby a 0.1 to 1000 nm (nanometre) thick layer is deposited.

Preferably, the protective metallic layer is deposited on at least one surface of the metal foil using a vacuum vaporisation process or by sputtering.

The protective metallic layer may be deposited to a thickness of 2 to 100 nm, preferably 5 to 50 nm, in particular 40 nm.

Usefully zirconium or titanium and preferably chromium is deposited as the protective metallic layer in the process according to the invention.

The metal foil coated with the protective metallic layer, preferably an aluminium foil coated with a chromium layer, is bonded on the one side to the base film, usefully by means of an adhesive layer such as an adhesive, a laminating adhesive, a sealing lacquer or film and/or a primer. On the other side of the metal foil, is vapour deposited protective metallic layer and, bonded to the protective metallic layer, is the functional plastic layer—in some cases via an adhesive layer such as an adhesive, a laminating adhesive, a sealing lacquer or film and/or a primer.

Accordingly, especially preferred plastic laminate films in accordance with the present invention are those where the base film of plastic are a 15 to 25 μm thick layer of polyamide, a 12 to 23 μm thick layer of polyethlene-terephthalate or a layer made up of two layers of oriented polyamide each 15 to 25 μm thick, the metal foil is of aluminium, 45 to 60 μm thick, the protective metallic layer is of chromium having a thickness of approx. 40 nm and the functional plastic layer comprises a 15 μm thick layer of oriented polyamide and 30 to 50 μm thick coextruded polypropylene or a 12 μm thick layer of polyethylene-terephthalate and 50 μm thick coextruded polypropylene or a 15 μm thick layer of oriented polyamide and 30 μm coextruded polyethylene or a 20 μm thick layer of oriented polypropylene and 30 to 50 μm thick coextruded polypropylene.

The plastic laminate film according to the invention is employed as battery cladding for battery modules of batteries and battery accumulators such as primary and secondary batteries, preferably lithium-ion batteries and lithium-polymer batteries,

For example, the plastic laminate film may be shape-formed into a bag shape, the battery module placed in the bag and the bag sealed, welded or adhesively bonded at its open end. The battery module may also be enclosed, wrapped or rolled up in a corresponding cut piece of plastic laminate film and the edges of the plastic laminate film can be sealed, welded or adhesively bonded together.

In yet another manner, it is possible to shape the plastic laminate film into a shaped body e.g. hot and preferably cold forming. The forming may be carried out by deep drawing, stretch-drawing or by a combination of both methods. Such bodies may be in the form of dishes, half-shells or box-shaped containers. The battery module is laid in the dish and the dish can be closed over by a film providing a lid. The lid film is in particular a suitable piece of the plastic laminate film according to the invention. The closing may be carried out using a sealing seam running along the edge of the dish. The battery module may also be placed in a lower half-shell and the lower half-shell covered over by an upper half-shell. The two half-shells are sealed along the edges making contact with each other and thus securely joined together. It is also possible for the module to be placed in an approximately box-shaped container and the inlet opening to be closed off by deforming the container or closing over the opening with a lid or a plastic laminate film. In each case the electrodes leading from the battery module have to be led through the cladding. Usefully, the electrodes are led through the inlet opening for the battery module. The electrodes may be led through the inlet opening of the bag, between dishes and lidding, through the seam between both half-shells or through the seam between the container and the lid. The sealing seam on the bag, dishes, half-shells and containers are advantageously at least impermeable to fluids, preferably air-tight or gas-tight, and secure against separation. The passage of the electrodes out of the receptacle should also be tightly sealed, so that no substances can pass along the electrodes neither into nor out of the receptacle. As required, it is possible to employ welding or adhesive bonding instead of sealing.

Preferred are battery claddings using a cold formed plastic laminate film. The plastic laminate films are preferably cold formed to give dish-shaped receptacles. By “cold formed” here is meant a shaping operation e.g. by deepening such as deep-drawing or stretch-drawing, at room temperature, approx. 20 to 30° C., and in some cases up to temperatures of approx. 50 to 70° C. The battery module may be placed in the dish, the electrodes led over the edge of the dish and the dish sealed tightly an securely to a lid film, usefully of the plastic laminate film according to the invention, or the dish can be sealed tightly and securely to a sealed-on shaped-lid part usefully made of the plastic laminate film according to the invention.

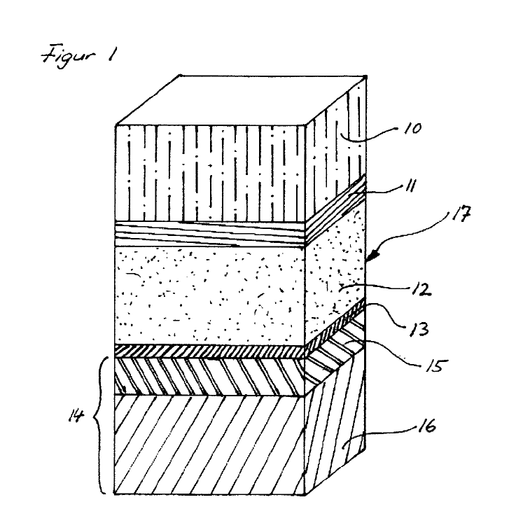

FIGS. 1 to 5 explain the invention in greater detail by way of examples.

FIGS. 1 to 4 show schematically the sequence of layers in the plastic laminate film according to the invention.

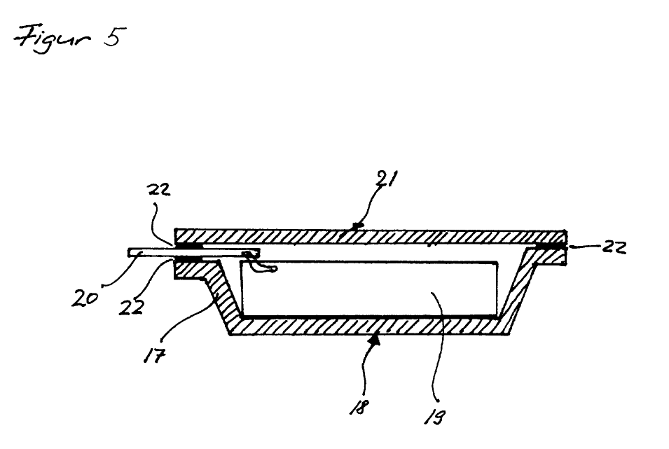

FIG. 5 shows a section through a battery in which a battery cladding according to the invention is employed

As shown in FIG. 1, an example of the plastic laminate layer (17) exhibits a layer structure comprising a base film (10), an adhesive layer (11), metal foil (12), metallic protective layer (13) and the functional layer (14) by way of example having a layer of a denaturised polyolefin (15) and a polyolefin layer (16). The base film (10) represents in particular the layer of battery cladding that faces outwards, and may be of oriented polyamide. The metal foil (12), such as an aluminium foil, on the side facing inwards toward the battery module, is coated with a 0.1 to 1000 nm thick protective metallic layer (13) deposited by physical deposition means e.g. a layer containing chromium ions. The protective metallic layer (13) provides excellent protection for the underlying metal foil (12) in particular against corrosion. Substances leaking from the battery module which are damaging to the metal foil (12) e.g. corrosive, can in some cases penetrate the functional layer (14) but are reliably held back by the vapour deposited protective metallic layer (13) and do not, therefore, reach the metal foil (12). Thus, such aggressive substances are not able to have their damaging—in particular, corrosive—influence on the metal foil (12). The metal foil (12) provides a barrier against penetration of moisture and gases. Corrosion and pitting cause this barrier action to be impaired or destroyed. Without this barrier action, not only would substances be able to leak out of the battery module, but also substances such as moisture could enter the battery module from outside. Impairment or damage to the metal foil (12) also causes delamination in the plastic laminate film. Delamination is avoided in that the above mentioned attack on the battery cladding is no longer able to take place.

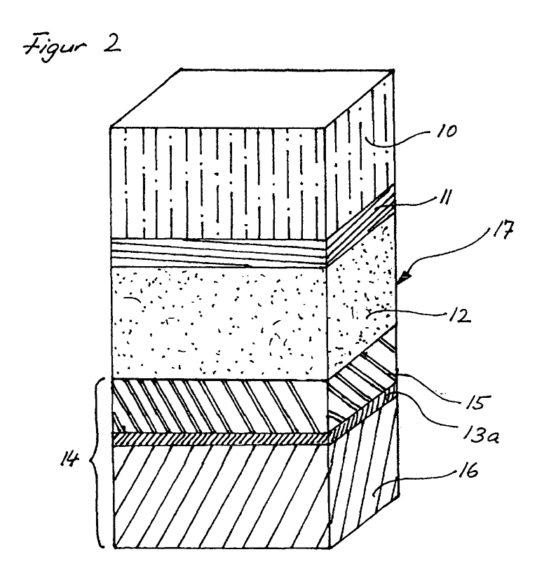

FIG. 2 shows an example of the plastic laminate film (17) with a layer structure comprising: a base film (10), adhesive layer (11), metal foil (12) and functional layer (14). The functional layer (14) is made up of layers of plastic (15, 16). Provided between the layers (15, 16) is the protective metallic layer (13a) deposited e.g. as a 40 nm thick layer e.g. containing chromium and using a physical deposition method. The protective metallic layer (13a) may, as the case requires, be vapour deposited either on the plastic layer (15) or plastic layer (16) or on both plastic layers (15, 16). After vapour deposition, the two plastic layers (15, 16) are fitted together in such a manner that the protective metallic layer (13a) is situated between the two plastic layers (15, 16).

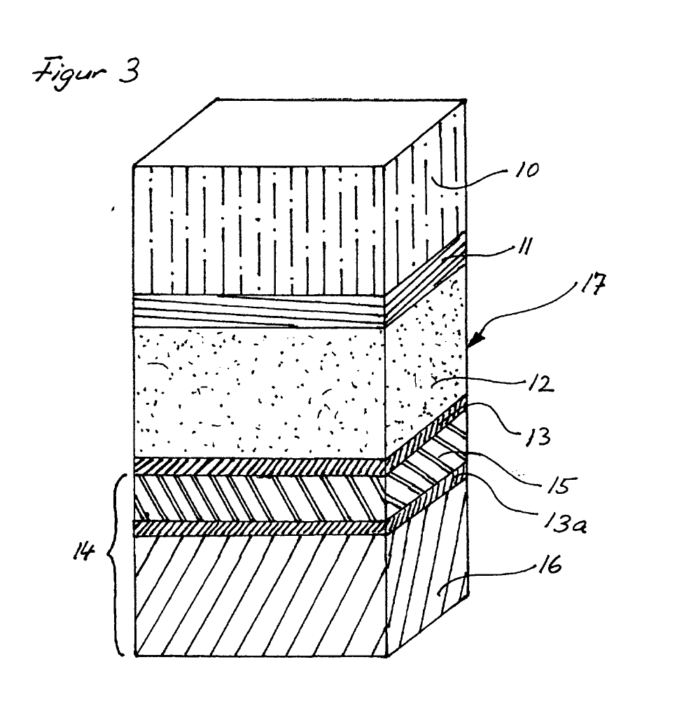

FIG. 3 shows an example of the plastic laminate film (17) with a layer structure comprising: base film (10), adhesive layer (11), metal foil (12), protective metallic layer (13) and functional layer (14). The functional layer (14) is made up of layers of plastic (15, 16). A second protective metallic layer (13a) is provided between the layers (15, 16). The protective metallic layer (13a) may, as the case requires, be vapour deposited either on plastic film (15) or plastic film (16) or on both plastic films (15, 16). After vapour deposition, the two plastic layers (15, 16) are fitted together in such a manner that the protective metallic layer (13a) is situated between the two plastic layers (15, 16).

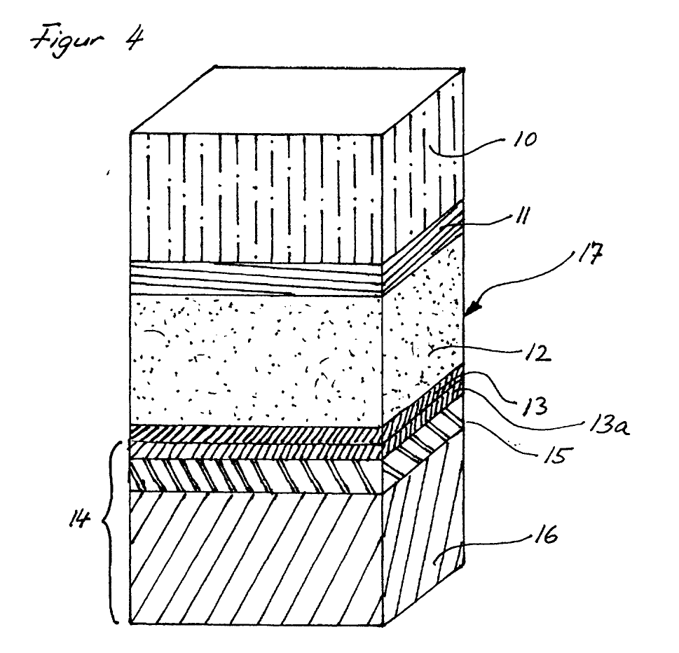

FIG. 4 shows an example of the plastic laminate film (17) having a layer structure comprising: base film (10), adhesive film (11), metal foil (12), protective metallic layer (13) and functional layer (14). The functional layer (14) is made up of layers of plastic (15, 16). A second protective metallic layer (13a) is provided on layer (15). The second protective metallic layer (13a) has been vapour deposited on the plastic layer (15). In some cases, as require, an adhesive layer or an adhesive (not shown here) may be provided between the two protective metallic layers (15, 16). For the sake of completeness, attention is drawn to another possible version of layer structure in accordance with FIG. 4. A third protective metallic layer may be provided between the layers of plastic (15, 16).

FIG. 5 shows a section through a battery. A battery module (19) is placed in a dish (18) e.g. of rectangular base shape, made from cold formed plastic laminate film (17) according to the invention. The electrodes (20) project out of the battery module and cross the edge of the dish (18). At the parts of the electrodes projecting from the dish (18) energy can be drawn from the battery when in use. The dish (18) is covered over by a lid-foil (21). The lid-foil (21) may e.g. be made of the same plastic laminate film (17) as the dish (18) is made from. An endless, securely joined sealing seam (22) is situated between the dish (18) and lid film (21) along the shoulder (22) of the dish (18). As a result the battery module is closed tightly against passage of gas, moisture and external influence.

### EXAMPLES

Examples of plastic laminate films according tot the invention are listed in the following tables.

| Base film, facing | | | Protective | | |
|---|---|---|---|---|---|
| outwards | | Metal foil | metallic | Functional layer, facing inwards | |
| Further layers, | | Al | layer Metal, | | Further layers, |
| employed as | | thickness in | thickness in | | employed as |
| required | | μm | nm | | required |
| | 15 μm | 40 μm | Cr, 40 nm | 15 μm | 30 μm PP-Co-ex |
| | oPA | | | oPA | |
| | 15 μm | 45 μm | Cr, 40 nm | 15 μm | 30 μm PP-Co-ex |
| | oPA | | | oPA | |
| | 15 μm | 60 μm | Cr, 40 nm | 15 μm | 30 μm PP-Co-ex |
| | oPA | | | oPA | |
| | 25 μm | 45 μm | Cr, 40 nm | 30 μm PP | |
| | oPA | | | Co-ex | |
| | 25 μm | 60 μm | Cr, 40 nm | 30 μm PP | |
| | oPA | | | Co-ex | |
| | 25 μm | 60 μm | Cr, 40 nm | 30 μm PP | |
| | oPA | | | Co-ex | |
| | 20 μm | 45 μm | Cr, 40 nm | 30 μm PP | |
| | oPA | | | Co-ex | |
| | 25 μm | 100 μm | Cr, 40 nm | 30 μm PP | |
| | oPA | | | Co-ex | |
| | 15 μm | 45 μm | Cr, 40 nm | 15 μm | 50 μm PP-Co-ex |
| | oPA | | | oPA | |
| | 15 μm | 60 μm | Cr, 40 nm | 15 μm | 50 μm PP-Co-ex |
| | oPA | | | oPA | |
| | 15 μm | 60 μm | Cr, 40 nm | Cr, 40 nm, | 50 μm PP-Co-ex |
| | oPA | | | 15 μm | |
| | | | | oPA | |
| | 25 μm | 45 μm | Cr, 40 nm | 50 μm PP | |
| | oPA | | | Co-ex | |
| | 25 μm | 60 μm | Cr, 40 nm | 50 μm PP | |
| | oPA | | | Co-ex | |
| | 25 μm | 60 μm | Cr, 40 nm | 50 μm PP | |
| | oPA | | | Co-ex | |
| | 20 μm | 45 μm | Cr, 40 nm | 50 μm PP | |
| | oPA | | | Co-ex | |
| | 25 μm | 100 μm | Cr, 40 nm | 50 μm PP | |
| | oPA | | | Co-ex | |
| | 12 μm | 45 μm | Cr, 40 nm | 12 μm | 50 μm PP Co-ex |
| | PET | | | PET | |
| | 12 μm | 60 μm | Cr, 40 nm | 12 μm | 50 μm PP Co-ex |
| | PET | | | PET | |
| | 23 μm | 45 μm | Cr, 40 nm | 50 μm PP | |
| | PET | | | Co-ex | |
| | 23 μm | 60 μm | Cr, 40 nm | 50 μm PP | |
| | PET | | | Co-ex | |
| | 23 μm | 60 μm | Cr, 40 nm | 50 μm PP | |
| | PET | | | Co-ex | |
| | 12 μm | 45 μm | Cr, 40 nm | 50 μm PP | |
| | PET | | | Co-ex | |
| | 23 μm | 100 μm | Cr, 40 nm | 50 μm PP | |
| | PET | | | Co-ex | |
| | 25 μm | 45 μm | Cr, 40 nm | 12 μm | 50 μm PP Co-ex |
| | oPA | | | PAN | |
| | 25 μm | 45 μm | Cr, 40 nm | 12 μm | 50 μm PP Co-ex |
| | oPA | | | PET | |
| | 25 μm | 60 μm | Cr, 40 nm | 12 μm | 50 μm PP Co-ex |
| | oPA | | | PET | |
| | 23 μm | 45 μm | Cr, 40 nm | 30 μm PP | |
| | PET | | | Co-ex | |
| | 23 μm | 60 μm | Cr, 40 nm | 30 μm PP | |
| | PET | | | Co-ex | |
| | 23 μm | 60 μm | Cr, 40 nm | 30 μm PP | |
| | PET | | | Co-ex | |
| | 12 μm | 45 μm | Cr, 40 nm | 30 μm PP | |
| | PET | | | Co-ex | |
| | 23 μm | 100 μm | Cr, 40 nm | 30 μm PP | |
| | PET | | | Co-ex | |
| | 15 μm | 45 μm | Cr, 40 nm | 15 μm | 30 μm PE-Co-ex |
| | oPA | | | CoC | |
| | 15 μm | 45 μm | Cr, 40 nm | 15 μm | 30 μm PE-Co-ex |
| | oPA | | | oPA | |
| | 15 μm | 60 μm | Cr, 40 nm | 15 μm | 30 μm PE-Co-ex |
| | oPA | | | oPA | |
| | 25 μm | 45 μm | Cr, 40 nm | 30 μm PE | |
| | oPA | | | Coex | |
| | 25 μm | 60 μm | Cr, 40 nm | 30 μm PE | |
| | oPA | | | Co-ex | |
| | 25 μm | 60 μm | Cr, 40 nm | 30 μm PE | |
| | oPA | | | Co-ex | |
| | 20 μm | 45 μm | Cr, 40 nm | 30 μm PE | |
| | oPA | | | Co-ex | |
| | 25 μm | 100 μm | Cr, 40 nm | 30 μm PE | |
| | oPA | | | Co-ex | |
| 25 μm oPA | 25 μm | 45 μm | Cr, 40 nm | 30 μm PP | |
| | oPA | | | Co-ex | |
| 25 μm oPA | 25 μm | 100 μm | Cr, 40 nm | 30 μm PE | |
| | oPA | | | Co-ex | |
| 20 μm oPA | 20 μm | 45 μm | Cr, 40 nm | 30 μm PP | |
| | oPA | | | Co-ex | |
| 20 μm oPA | 20 μm | 100 μm | Cr, 40 nm | 30 μm PE | |
| | oPA | | | Co-ex | |
| 15 μm oPA | 15 μm | 45 μm | Cr, 40 nm | 30 μm PP | |
| | oPA | | | Co-ex | |
| 15 μm oPA | 15 μm | 100 μm | Cr, 40 nm | 30 μm PE | |
| | oPA | | | Co-ex | |
| | 20 μm | 100 μm | Cr, 40 nm | 30 μm PE | |
| | oPP | | | Co-ex | |
| | 25 μm | 40 μm | Cr, 40 nm | 20 μm oPP | 50 μm PP Co-ex |
| | oPA | | | | |
| | 25 μm | 45 μm | Cr, 40 nm | 20 μm oPP | 50 μm PP Co-ex |
| | oPA | | | | |
| | 25 μm | 45 μm | Cr, 40 nm | 20 μm oPP | 30 μm PP Co-ex |
| | oPA | | | | |
| | 15 μm | 45 μm | Cr, 40 nm | 20 μm oPP | 50 μm PP Co-ex |
| | oPA | | | | |
| | 15 μm | 45 μm | Cr, 40 nm | 20 μm oPP | 30 μm PP Co-ex |
| | oPA | | | | |

As desired, instead of a PP Co-ex or PE-Co-ex layer, a laminated or hot-calendared PP or PE film may be employed in the examples shown in the table.

The abbreviations in the table have the following meaning:

The values of thickness of plastic films or layers are expressed in μm.

oPA: oriented polyamide

PET: polyethylene-terephtalate

oPP: oriented polypropylene

Al: aluminium

Cr: chromium

nm: nanometre

PP: polypropylene

PE: polyethylene

PAN: polyacrylnitrile

CoC: cycloolefinic copolymer

Co-ex: co-extruded.

1. A plastic laminate film comprising:
a base film of plastic;
a metal foil; and
a functional plastic layer, wherein the base film, the metal foil, and the functional plastic layer are superimposed over one another; and
at least one protective metallic layer having a thickness of 0.1 to 1000 nm deposited by a physical deposition process on at least one of:
(a) the metal foil, at least on a side facing the functional plastic layer, and
(b) the functional plastic layer, at least of (1) on a side facing the metal foil and (2) within the functional plastic layer.

2. A plastic laminate film according to claim 1, wherein the protective metallic layer exhibits a thickness of 2 to 100 nm.

3. A plastic laminate film according to claim 1, wherein the protective metal layer is created by a vacuum vapour deposition process or by sputtering.

4. A plastic laminate film according to claim 1, wherein the protective metallic layer comprises a metal selected from a group consisting of: chromium, titanium and zirconium.

5. A plastic laminate film according to claim 1, wherein:
the base film of plastic comprises a layer selected from a group consisting of: a 15 to 25 μm thick oriented polyamide layer, a 12 to 23 μm thick polyethylene-terephthalate layer and a layer comprising two layers of oriented polyamide each having a thickness of 15 to 25 μm,
the metal foil comprises aluminium having a thickness of 45 to 60 μm,
the protective metallic layer comprises chromium having a thickness of 40 nm, and
the functional plastic layer comprises a layer selected from a group consisting of: (a) a 15 μm thick layer of oriented polyamide and 30 to 50 μm thick co-extruded polypropylene, (b) a layer of 12 μm thick polyethylene-terephthalate and 50 μm thick co-extruded polypropylene, (c) a layer of 15 μm thick oriented polyamide and 30 μm thick co-extruded polyethylene, and (d) a layer of 20 μm thick oriented polypropylene and 20 to 50 μm thick co-extruded polypropylene.

6. A battery cladding for battery modules comprising a plastic laminate film according to claim 1.

7. A battery cladding according to claim 6, making use of a cold formed plastic laminate film.

8. A process for manufacturing a plastic laminate film, the process comprising:
providing a base film of plastic, a metal foil, and a functional plastic layer;
depositing at least one protective metallic layer having a thickness of 0.1 to 1000 nm by a vapour deposition process on at least one of:
(a) the metal foil, at least on a side configured to face the functional plastic layer, and
(b) the functional plastic layer, at least one of (1) on a side configured to face the metal foil and (2) within the functional plastic layer; and
connecting the base film, the metal foil, and the functional plastic layer such that the layers are superimposed over one another.

9. A process for manufacturing a plastic laminate film according to claim 8, wherein the metallic protective layer is deposited on at least one surface of the metal foil using a technique selected from a group consisting of: a vacuum deposition process and sputtering.

10. A process for manufacturing a plastic laminate film according to claim 8, wherein the protective metallic layer is deposited to a thickness of 2 to 100 nm.

11. A process for manufacturing a plastic laminate film according to claim 8, wherein the protective metallic layer comprises a metal selected from a group consisting of: chromium, zirconium, and titanium.

12. A process for manufacturing a plastic laminate film according to claim 8, wherein the deposition of the protective metallic layer is carried out using a chromium deposition process, whereby the base film is joined to the metal foil or the functional layer in a vacuum chamber in an oxygen plasma, and after that exposed to a chromium-containing cloud created by electron beam vaporisation, and a chromium layer is deposited as the protective metallic layer.

13. A process for manufacturing a plastic laminate film according to claim 8, wherein the protective metallic layer is deposited to a thickness of 5 to 50 nm.

14. A process for manufacturing a plastic laminate film according to claim 13, wherein the protective metallic layer is deposited to a thickness of 40 nm.

15. A plastic laminate film according to claim 2, wherein the protective metallic layer exhibits a thickness of 5 to 50 nm.

16. A plastic laminate film according to claim 15, wherein the protective metallic layer exhibits a thickness of 40 nm.
